(19) United States
(12) Patent Application Publication
(10) Pub. No.: US 2009/0168573 A1
(43) Pub. Date: Jul. 2, 2009

(54) ADAPTIVE MEMORY ARRAY VOLTAGE ADJUSTMENT

(76) Inventors: Ming Zhang, Sunnyvale, CA (US); Balkaran Gill, Cornelius, OR (US); Greg Taylor, Portland, OR (US)

Correspondence Address: INTEL CORPORATION;c/o CPA Global, P.O. BOX 52050, MINNEAPOLIS, MN, 55402, US

(21) Appl. No.: 11/967,830

(22) Filed: Dec. 31, 2007

(51) Int. Cl. G11C 5/14; G11C 29/52; G11C 7/04

(52) U.S. Cl. 365/201; 365/226

(57) ABSTRACT

In some embodiments a sensor is to sense a temperature of a memory occurring in the memory during active use of the memory. A controller is to adjust a voltage supply of the memory during active use of the memory in response to the sensed temperature. In some embodiments a monitor is to monitor errors occurring in a memory during active use of the memory, and a controller is to adjust a voltage supply of the memory during active use of the memory in response to the monitored errors. Other embodiments are described and claimed.

### TECHNICAL FIELD

The inventions generally relate to adaptive memory array voltage adjustment.

### BACKGROUND

Memory arrays are an important part of computing devices. Memory circuits can exhibit uncertain behavior (for example, erratic bits) as a result of soft defects in transistors. Common practice is to compensate such uncertain circuit behavior by adding a margin or a guardband to a minimum voltage supply (Vccmin). Temperature fluctuation or erratic bits can cause a change in the minimum voltage supply (Vccmin) requirements of the memory array. If the Vccmin margin or guardband is necessarily increased due to such a temperature fluctuation or erratic bits, the average power of the memory array may be increased and the performance per watt of the memory array may be reduced. Vccmin of a memory array can be a dominating bottleneck for server chips with large memory arrays or for low power designs such as an ultra mobile personal computer (UMPC) or a mobile internet device (MID), for example. Therefore, reducing the time-0 Vccmin guardband (GB) is extremely important in improving the performance per Watt and/or battery life characteristics of the computing device. The present inventors have observed, for example, large margins between Vccmin when a memory array is operating at hot temperatures vs. cold temperatures of approximately 110 mv difference between a memory array operating at 90 C (90 degrees Celsius) and 0 C (0 degrees Celsius). The present inventors have also observed a fluctuation in Vccmin of approximately 100 mv to 150 mv due to erratic bits in the memory array.

One approach to improving average power has been to include a time-0 guardband (GB) for temperature fluctuation and/or erratic bits. However, the total guardband of such an arrangement is typically 100 mv to 200 mv, which is a large amount compared to a target Vcc value in the range of 700 mv to 800 mv. Single-bit fix (SBF) technology has been used to filter a limited number of recurring single-bit errors from MCA (Memory Check Arhitecture). Cache line disabling (CLD) has been used to replace “bad” cache lines with redundant lines. CLD is activated during POST (power on self test) only so it does not address problems that arise during active use of the memory array. Therefore, the present inventors have recognized that there is a need for better correction of such problems.

### BRIEF DESCRIPTION OF THE DRAWINGS

The inventions will be understood more fully from the detailed description given below and from the accompanying drawings of some embodiments of the inventions which, however, should not be taken to limit the inventions to the specific embodiments described, but are for explanation and understanding only.

FIG. 1 illustrates a system according to some embodiments of the inventions.

FIG. 2 illustrates a flow according to some embodiments of the inventions.

FIG. 3 illustrates a flow according to some embodiments of the inventions.

### DETAILED DESCRIPTION

Some embodiments of the inventions relate to adaptive memory array voltage adjustment.

In some embodiments a sensor is to sense a temperature of a memory occurring in the memory during active use of the memory, and a controller is to adjust a voltage supply of the memory during active use of the memory in response to the sensed temperature.

In some embodiments a monitor is to monitor errors occurring in a memory during active use of the memory, and a controller is to adjust a voltage supply of the memory during active use of the memory in response to the monitored errors.

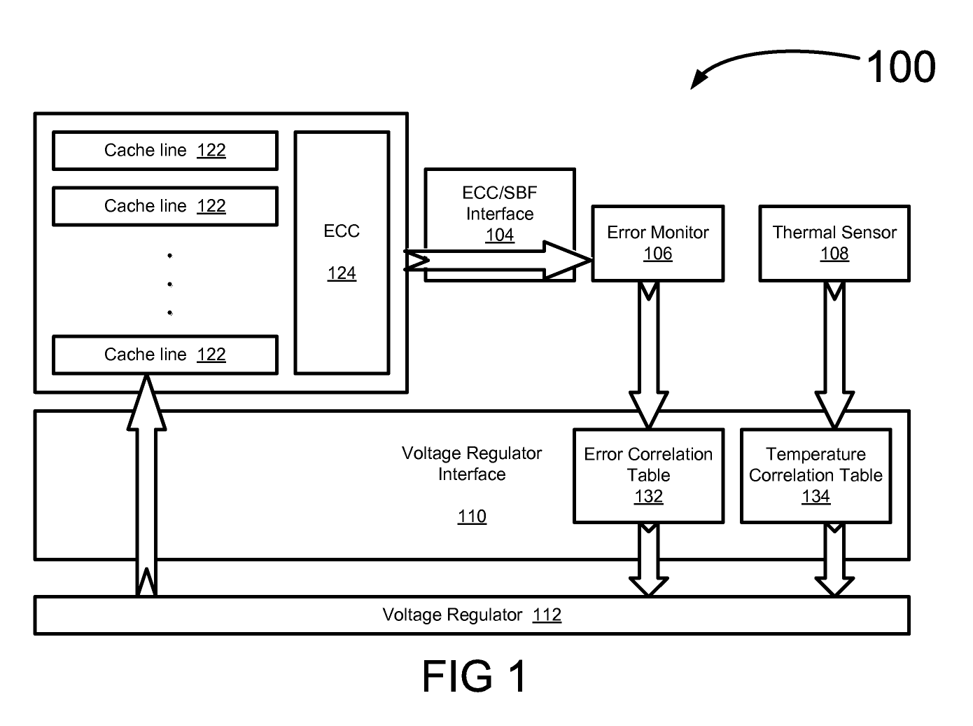

FIG. 1 illustrates a system 100 according to some embodiments. In some embodiments system 100 includes a memory 102, an ECC/SBF interface 104, an error monitor 106 (for example, including an error counter and/or a threshold checker), a thermal sensor 108, a voltage regulator interface 110 (for example, a voltage regulator module interface and/or a VRM interface), and a voltage regulator 112 (for example, a voltage regulator module and/or a VRM). Memory 102 includes one or more cache lines 122 and Error Correcting Code (ECC) 124. Voltage regulator interface 110 includes an error correlation table 132 and a temperature correlation table 134.

In some embodiments, system 100 adaptively reduces the Vccmin margin and/or guardband caused by temperature fluctuation or erratic bits. This leads to a lower average power use of the memory array and improved performance of the memory array per Watt.

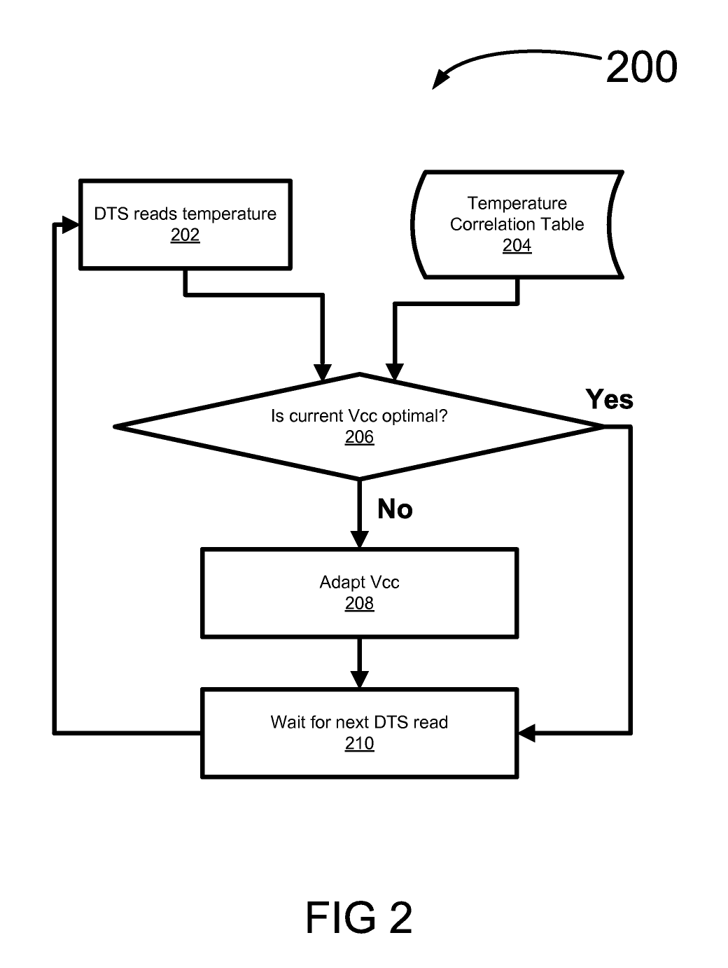

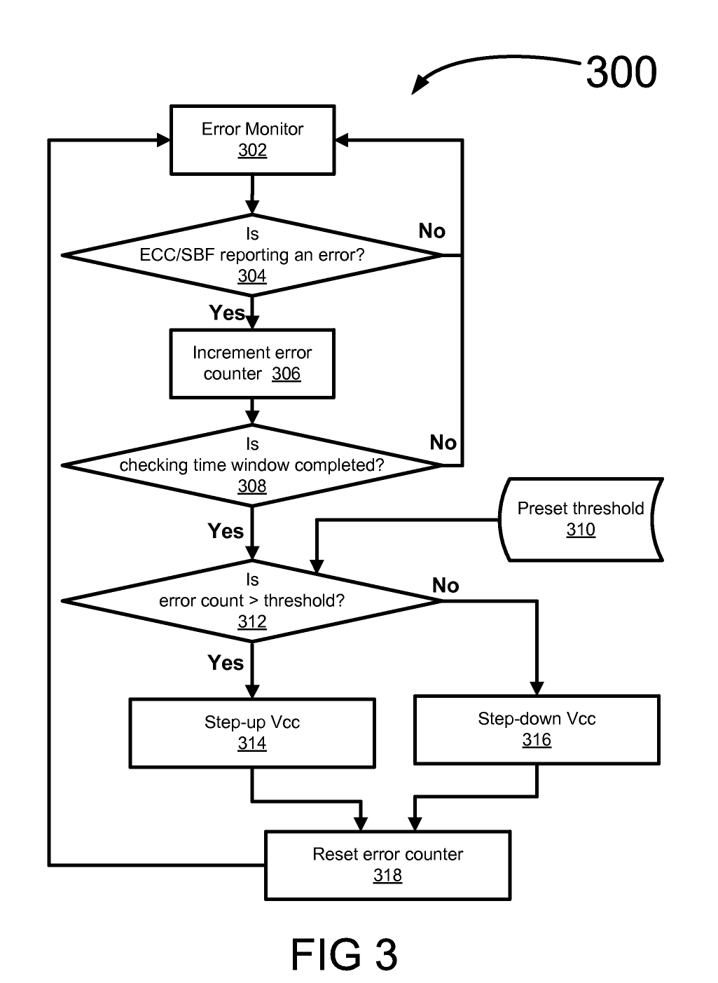

In some embodiments, system 100 can operate in two modes. In a first mode using an open-loop configuration, the Vccmin margin caused by temperature fluctuations is reduced. In a second mode using a closed-loop configuration, the Vccmin margin caused by both temperature fluctuations and erratic bits is reduced. System 100 can operate in the first mode only, the second mode only, or in both modes simultaneously. The first mode of operation is described herein, for example, in reference to system 100 in FIG. 1 and flow 200 in FIG. 2. The second mode of operation is described herein, for example, in reference to system 100 in FIG. 1 and flow 300 in FIG. 3.

In a first mode of operation according to some embodiments, the thermal sensor 108 and the temperature correlation table 134 of the voltage regulator interface 110 and/or the voltage regulator 110 are activated in a configuration that can be thought of as a generalized performance state driven by temperature.

In some embodiments, the temperature correlation table 134 is constructed in the factory by characterizing the Vccmin of the memory at different temperature points. In some embodiments, this table is similar to an ACPI (Advanced Configuration and Power Interface) table that is burned into the BIOS (Basic Input/Output System) for CPU (Central Processing Unit) performance state controls (for example, for mobile computing devices). In any case, in some embodiments, temperature correlation table 134 may be provided as a part of an extended ACPI table stored in the BIOS memory.

FIG. 2 illustrates a flow 200 according to some embodiments. At 202 a digital thermal sensor (DTS) (for example, in some embodiments, thermal sensor 108 of FIG. 1) located near the memory array provides a periodic temperature reading that is accurate, for example, within 1 C (one degree Celsius). Upon comparison with the value in the temperature correlation table 204 (and/or the temperature correlation table 134 of FIG. 1), a decision is made at 206 as to whether the current Vcc is an optimal value. Upon this comparison, the voltage regulator interface 110 of FIG. 1, for example, can determine the optimal Vccmin setting based on the current temperature reading, for example, using the temperature correlation table 204 and/or the temperature correlation table 134. If at 206 the optimal value is not consistent with the current Vccmin setting of the memory (for example, memory 102) an adaptation request is initiated and sent to the voltage regulator (and/or voltage regulator module) such as, for example, voltage regulator 112 of FIG. 1. In this manner the Vcc is adapted at 208 by driving the more optimal Vcc value back to the circuits of the memory (for example, via voltage regulator 112 and voltage regulator interface 1 10). Otherwise, if at 206 the current Vcc is consistent with the current Vccmin setting of the memory, no action is necessary and the Vcc is maintained at the present value until the next time the DTS reads the temperature. After adapting the Vcc at 208 or if the current Vcc is already optimal at 206, flow moves to 210 to wait for the next DTS read (for example, by waiting a predetermined amount of time until the next DTS reading).

In some embodiments, a temperature correlation table (for example, table 134 and/or table 204) with a resolution of 10 C is appropriate. In some embodiments, an example of a portion of such a temperature correlation table is:

| Temperature | Optimal Vccmin value |
|---|---|
| 0 C. | 900 mV |
| 10 C. | 890 mV |
| . . . | . . . |
| 100 C. | 800 mV |

As a result of the mode of operation illustrated in FIG. 2 and described in reference thereto, a memory would only operate at a higher Vcc when necessary, for example, since in some embodiments Vccmin tends to be higher at colder temperatures. Since temperature fluctuation can often be responsible for up to 100 mV of Vccmin change, this adaptive Vccmin adjustment implementation based on temperature reading (for example, DTS reading) leads to a savings of average power used by the memory array.

In a second mode of operation according to some embodiments, the ECC/SBF interface 104, the error monitor 106, and the error correlation table 132 of the voltage regulator interface 110 and/or the voltage regulator 132 are activated. The second mode of operation can be thought of as a low pass filter operation that prevents the voltage regulator 112 from reacting to rare errors (caused for example, by soft errors) which is a more advanced or aggressive implementation than typical SBF technology.

FIG. 3 illustrates a flow 300 according to some embodiments. At 302 every time the ECC/SBF infrastructure (for example, ECC/SBF interface 104) reports a singe detected error on a cache line (for example, one of cache lines 122), the error counter is incremented at 306. In some embodiments, for example, ECC/SBF interface 104 filters a limited number of recurring single-bit errors from the MCA for SECDED (Single-error correction double-error detection). In fact, different embodiments include different ways of detecting such errors. At 302 an error monitor (for example, error monitor 106) monitors any detected errors from the ECC/SBF interface (for example, ECC/SBF interface 104) and a determination is made at 304 to increment the error counter at 306. If no error is reported at 304 or if the checking window is not complete at 308, flow returns to monitoring errors at 302. Once the checking window is complete at 308 (for example, after a certain period of time), the counted recorded errors are compared against a pre-set threshold at 312. If the error count is greater than the threshold at 312, then it means that the current Vcc setting is encroaching on the Vccmin limit and the Vcc value is stepped up at 314 (for example, using a voltage regulator interface such as interface 110 of FIG. 1 and/or a voltage regulator such as voltage regulator 112 of FIG. 1). If the error count is not greater than the threshold at 312, then the current Vcc setting is not aggressive enough (that is, there is too much margin or guardband), and action is taken at 316 to step-down the Vccmin setting (for example, using a voltage regulator interface such as interface 110 of FIG. 1 and/or a voltage regulator such as voltage regulator 112 of FIG. 1). After stepping-up the Vccmin value at 314 or stepping-down the Vccmin value at 316, the error counter is reset at 318 and flow 300 returns to the error monitoring at 302.

In some embodiments, Vcc may not always be stepped-up or stepped-down. For example, the Vcc value may be correct in some embodiments (for example, using a threshold value of number of errors) such that no changing of the value is necessary in some movements through flow 300 according to some implementations.

It is noted that the stepping-up and stepping-down of the Vcc values is an interactive and continuing adaptive process due to the closed-loop nature of the configuration. Therefore, the adaptation process is an inherently robust process that works well with unpredictable Vccmin fluctuations due to erratic bits, for example. Vccmin uncertainty caused by temperature fluctuation is appropriately mitigated.

In some embodiments, average power use by a memory array is improved by avoiding a large Vccmin guardband dedicated to temperature fluctuations and erratic bits. In some embodiments, open-loop and/or closed-loop configurations adaptively change the Vcc of the memory, resulting in lower average power consumption and/or improved performance per Watt. In some embodiments, Vccmin uncertainty is addressed using an adaptive design that employs the open-loop and/or closed-loop solution to adaptively change the Vcc on the memory.

Although some embodiments have been described herein as being implemented in a certain manner, according to some embodiments these particular implementations may not be required.

Although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Some embodiments may be implemented in one or a combination of hardware, firmware, and software. Some embodiments may also be implemented as instructions stored on a machine-readable medium, which may be read and executed by a computing platform to perform the operations described herein. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other form of propagated signals (e.g., carrier waves, infrared signals, digital signals, the interfaces that transmit and/or receive signals, etc.), and others.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although flow diagrams and/or state diagrams may have been used herein to describe embodiments, the inventions are not limited to those diagrams or to corresponding descriptions herein. For example, flow need not move through each illustrated box or state or in exactly the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

1. A method comprising:
sensing a temperature of a memory during active use of the memory;
adjusting a voltage supply of the memory during active use of the memory in response to the sensed temperature.

2. The method of claim 1, further comprising repeating the sensing and the adjusting during the active use of the memory.

3. The method of claim 1, further comprising:
referring to a temperature correlation table of optimal voltage supply values of the memory for different temperatures; and
adjusting the voltage supply in response to the temperature correlation table.

4. The method of claim 1, further comprising:
monitoring errors occurring in the memory during active use of the memory; and
adjusting the voltage supply of the memory during active use of the memory in response to the monitored errors.

5. The method of claim 4, further comprising repeating the monitoring and the adjusting during the active use of the memory.

6. The method of claim 4, further comprising comparing a number of the monitored errors with a threshold value and adjusting the voltage supply in response to the comparing.

7. (canceled)

8. (canceled)

9. (canceled)

10. An apparatus comprising:
a sensor to sense a temperature of a memory during active use of the memory;
a controller to adjust a voltage supply of the memory during active use of the memory in response to the sensed temperature.

11. The apparatus of claim 10, the sensor further to repeat the sensing and the controller to repeat the adjusting during the active use of the memory.

12. The apparatus of claim 10, the further comprising a temperature correlation table of optimal voltage supply values of the memory for different temperatures, the controller to adjust the voltage supply in response to the temperature correlation table.

13. The apparatus of claim 10, further comprising:
a monitor to monitor errors occurring in the memory during active use of the memory, the controller to adjust the voltage supply of the memory during active use of the memory in response to the monitored errors.

14. The apparatus of claim 13, the monitor to repeat the monitoring and the controller to repeat the adjusting during the active use of the memory.

15. The apparatus of claim 13, the controller to compare a number of the monitored errors with a threshold value and to adjust the voltage supply in response to the compare.

16. (canceled)

17. (canceled)

18. (canceled)

19. The method of claim 1, wherein the sensing of the temperature of the memory senses a temperature occurring in the memory during active use of the memory.

20. The apparatus of claim 10, wherein the sensor is to sense a temperature occurring in the memory during active use of the memory.
